(19) United States
(12) Patent Application Publication
(10) Pub. No.: US 2025/0287599 A1
(43) Pub. Date: Sep. 11, 2025

(54) SEMICONDUCTOR DEVICE

(71) Applicant: Kioxia Corporation, Tokyo (JP)

(72) Inventor: Kazunari TOYONAGA, Yokkaichi (JP)

(73) Assignee: Kioxia Corporation, Tokyo (JP)

(21) Appl. No.: 18/883,695

(22) Filed: Sep. 12, 2024

(30) Foreign Application Priority Data
Mar. 11, 2024 (JP) 2024-037387

(51) Int. Cl. H10B 43/40; G11C 16/08; H01L 23/00; H01L 25/065; H01L 25/18; H10B 43/27; H10B 80/00

(52) U.S. Cl. CPC H10B 43/40; G11C 16/08; H01L 24/08; H01L 25/0657; H01L 25/18; H10B 43/27; H10B 80/00; H01L 2224/08145; H01L 2924/1431; H01L 2924/14511

(57) ABSTRACT

A semiconductor device includes a first semiconductor layer, first transistors, and second transistors. The first semiconductor layer includes a first face and a second face and includes a concave region and a convex region on the first face. The first transistors each include a first gate dielectric film located in the convex region of the first semiconductor layer, a side gate dielectric film located on sidewalls of the convex region, a first gate electrode located on the first gate dielectric film, and a side gate electrode located on the side gate dielectric film and connected to the first 10 gate electrode. The second transistors each include a second gate dielectric film located on the convex region and being thinner than the first gate dielectric film, and a second gate electrode located on the second gate dielectric film.

### CROSS REFERENCE TO RELATED APPLICATIONS

This application is based upon and claims the benefit of priority from the prior Japanese Patent Application No. 2024-037387, filed on Mar. 11, 2024, the entire contents of which are incorporated herein by reference.

### FIELD

The embodiments of the present invention relate to a semiconductor device.

### BACKGROUND

Semiconductor devices in which a plurality of transistors are formed on a semiconductor substrate are known.

### BRIEF DESCRIPTION OF THE DRAWINGS

FIG. 1 is a block diagram illustrating a configuration example of a semiconductor storage device according to a first embodiment;

FIG. 2 is a sectional view illustrating a configuration example of the semiconductor storage device according to the first embodiment;

FIG. 3 is a schematic plan view illustrating a stacked body;

FIG. 4 is a sectional view illustrating memory cells of a three-dimensional structure;

FIG. 5 is a sectional view illustrating the memory cells of a three-dimensional structure;

FIG. 6 is a plan view illustrating a configuration example of transistors constituting logic circuits of a CMOS chip according to the first embodiment;

FIG. 7 is a sectional view illustrating a configuration example of the transistors constituting the logic circuits of the CMOS chip according to the first embodiment;

FIG. 8 is a plan view illustrating a configuration example of transistors constituting word line switches of the CMOS chip according to the first embodiment;

FIG. 9 is a sectional view illustrating a configuration example of the transistors constituting the word line switches of the CMOS chip according to the first embodiment;

FIG. 10 is a sectional view illustrating an example of a manufacturing method of a transistor according to the first embodiment;

FIG. 11 is a sectional view illustrating an example of the manufacturing method of a transistor subsequent to FIG. 10;

FIG. 12 is a sectional view illustrating an example of the manufacturing method of a transistor subsequent to FIG. 11;

FIG. 13 is a sectional view illustrating an example of the manufacturing method of a transistor subsequent to FIG. 12;

FIG. 14 is a sectional view illustrating an example of the manufacturing method of a transistor subsequent to FIG. 13;

FIG. 15 is a sectional view illustrating an example of the manufacturing method of a transistor subsequent to FIG. 14; and

FIG. 16 is a sectional view illustrating a configuration example of transistors constituting word line switches according to a second embodiment.

### DETAILED DESCRIPTION

In general, according to the embodiment, a semiconductor device includes a first semiconductor layer, first transistors, and second transistors. The first semiconductor layer includes a first face and a second face on the opposite side to the first face, and includes a concave region recessed from the first face toward the second face and a convex region protruded with respect to the concave region. The first transistors each include a first gate dielectric film located in the convex region of the first semiconductor layer, a side gate dielectric film located on sidewalls of the convex region, a first gate electrode located on the first gate dielectric film, and a side gate electrode located on the side gate dielectric film and connected to the first gate electrode. The second transistors each include a second gate dielectric film located on the convex region and being thinner than the first gate dielectric film, and a second gate electrode located on the second gate dielectric film. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

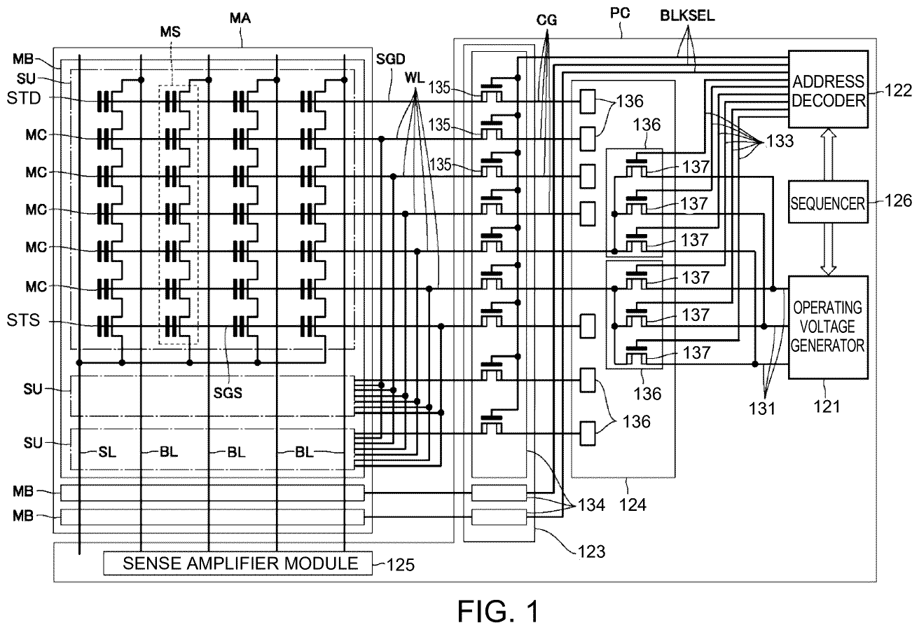

FIG. 1 is a block diagram illustrating a configuration example of a semiconductor storage device according to a first embodiment. The semiconductor storage device is, for example, a semiconductor memory such as a NAND flash memory. The semiconductor storage device includes a memory cell array MA, and peripheral circuits PC functioning as control circuits that control the memory cell array MA.

The memory cell array MA includes a plurality of memory blocks MB. Each of these memory blocks MB includes a plurality of string units SU. Each of these string units SU includes a plurality of memory strings MS. One ends of the memory strings MS are connected to the peripheral circuits PC with corresponding bit lines BL. The other ends of the memory strings MS are connected to the peripheral circuits PC with a common source layer SL.

Each of the memory strings MS includes a drain-side selection transistor STD, a plurality of memory cells MC, and a source-side selection transistor STS connected in series between the corresponding bit line BL and the source layer SL. Hereinafter, the drain-side selection transistor STD and the source-side selection transistor STS are also referred to simply as “selection transistors STD and STS”, or the like.

Each of the memory cells MC is an FET (Field Effect Transistor) including a semiconductor layer functioning as a channel region, a gate dielectric film including a charge accumulating film, and a gate electrode. The threshold voltage of each memory cell MC varies according to the amount of charges in the charge accumulating film. A word line WL is connected to the gate electrode of each of the memory cells MC corresponding to one memory string MS. Each of these word lines WL is connected in common to all the memory strings MS in one memory block MB.

The memory cells MC are provided corresponding to intersections between the word lines WL and the bit lines BL, respectively, and data can be written into or read from a memory cell MC through the corresponding bit line BL by application of a write voltage or a read voltage between the corresponding word line WL and the bit line BL. Data can be erased from the memory cell MC by application of an erase voltage between the corresponding word line WL and the corresponding bit line BL.

The selection transistors STD and STS are FETs each including a semiconductor layer functioning as a channel region, a gate dielectric film, and a gate electrode. Selection gate lines SGD and SGS are connected to the gate electrodes of the selection transistors STD and STS, respectively. The drain-side selection gate line SGD is provided corresponding to each of the string units SU and is connected in common to all the memory strings MS in one string unit SU. The source-side selection gate line SGS is connected in common to all the memory strings MS in the string units SU in one memory block MB. A structure in which the source-side selection transistor STS, the memory cells MC, and the drain-side selection transistor STD are connected in series is referred to as “memory string” or “string unit”.

The peripheral circuits PC include an operating voltage generator 121 that generates an operating voltage, an address decoder 122 that decodes address data, a block selection circuit 123 and a voltage selection circuit 124 that transfer the operating voltage to the memory cell array MA in accordance with an output signal from the address decoder 122, a sense amplifier module 125 connected to the bit lines BL, and a sequencer 126 that controls these components.

The operating voltage generator 121 includes a plurality of operating voltage output terminals 131. The operating voltage generator 121 includes, for example, a step-down circuit such as a regulator, and a step-up circuit such as a charge pump circuit. The operating voltage generator 121 sequentially generates a plurality of operating voltages to be applied to the bit lines BL, the source layer SL, the word lines WL, and the selection gate lines SGD and SGS at the time of a read operation, a write operation, and an erase operation for the memory cell array MA in accordance with a control signal from the sequencer 126, and outputs the generated operating voltages to the operating voltage output terminals 131. The operating voltages output from the operating voltage output terminals 131 are appropriately adjusted in accordance with a control signal from the sequencer 126.

The address decoder 122 includes a plurality of block selection lines BLKSEL and a plurality of voltage selection lines 133. For example, the address decoder 122 sequentially refers to address data in an address register in accordance with a control signal from the sequencer 126, decodes the address data, brings a block drive transistor 135 and voltage selection transistors 137 corresponding to the address data to an ON-state, and brings other block drive transistors 135 and other voltage selection transistors 137 to an OFF-state. For example, in a case where the block drive transistors 135 and the voltage selection transistors 137 are N-channel transistors, the address decoder 122 brings the voltages of a block selection line BLKSEL and a voltage selection line 133 corresponding to the address data to an “H” state and brings other voltages to an “L” state. In a case where the block drive transistors 135 and the voltage selection transistors 137 are P-channel transistors, it suffices to apply the opposite voltages to the block selection lines BLKSEL and the voltage selection lines 133.

In the illustrated example, the address decoder 122 includes one block selection line BLKSEL for one memory block MB. However, this configuration can be appropriately changed. For example, one block selection line BLKSEL may be provided for two or more memory blocks MB.

The block selection circuit 123 includes a plurality of block selectors 134 each corresponding to one memory block MB. Each of these block selectors 134 includes a plurality of the block drive transistors 135 corresponding to the word lines WL and the selection gate lines SGD and SGS, respectively. The block drive transistors 135 are, for example, high breakdown voltage (HV (High Voltage)) transistors. The drain electrode (or the source electrode) of each of the block drive transistors 135 is electrically connected to the corresponding word line WL or selection gate line SGD or SGS. Each of the source electrodes (or the drain electrodes) is electrically connected to the operating voltage output terminal 131 via a line CG and the voltage selection circuit 124. The gate electrodes thereof are connected in common to the corresponding block selection line BLKSEL.

The block selection circuit 123 further includes a plurality of transistors (not illustrated). These transistors are high breakdown voltage (HV) transistors connected between the selection gate line SGD or SGS and a ground voltage supply terminal. These transistors bring the selection gate lines SGD and SGS included in non-selected memory blocks MB to induction with the ground voltage supply terminal. The word lines WL included in the non-selected memory blocks MB are brought to a floating state.

The voltage selection circuit 124 includes a plurality of voltage selectors 136 corresponding to the word lines WL and the selection gate lines SGD and SGS. Each of these voltage selectors 136 includes a plurality of the voltage selection transistors 137. The voltage selection transistors 137 are, for example, high breakdown voltage (HV) transistors. The drain terminals (or the source terminals) of the voltage selection transistors 137 are electrically connected to the corresponding word lines WL and selection gate lines SGD and SGS via the corresponding lines CG and the block selection circuit 123, respectively. The source terminals (or the drain terminals) are electrically connected to the corresponding operating voltage output terminals 131, respectively. The gate electrodes are connected to the corresponding voltage selection lines 133, respectively.

The sense amplifier module 125 is connected to the bit lines BL. The sense amplifier module 125 includes, for example, a plurality of sense amplifier units corresponding to the bit lines BL. Each of the sense amplifier units includes a clamp transistor that charges a bit line BL on the basis of the voltage generated by the operating voltage generator 121, a sense transistor that senses the voltage or current of the bit line BL, and a plurality of latch circuits that retain an output signal, data to be written, and the like of the sense transistor.

The sequencer 126 outputs a control signal to the operating voltage generator 121, the address decoder 122, and the sense amplifier module 125 according to an input command and the state of the semiconductor device. For example, the sequencer 126 sequentially refers to command data in a command register in accordance with a clock signal, decodes the command data, and outputs the decoded data to the operating voltage generator 121, the address decoder 122, and the sense amplifier module 125.

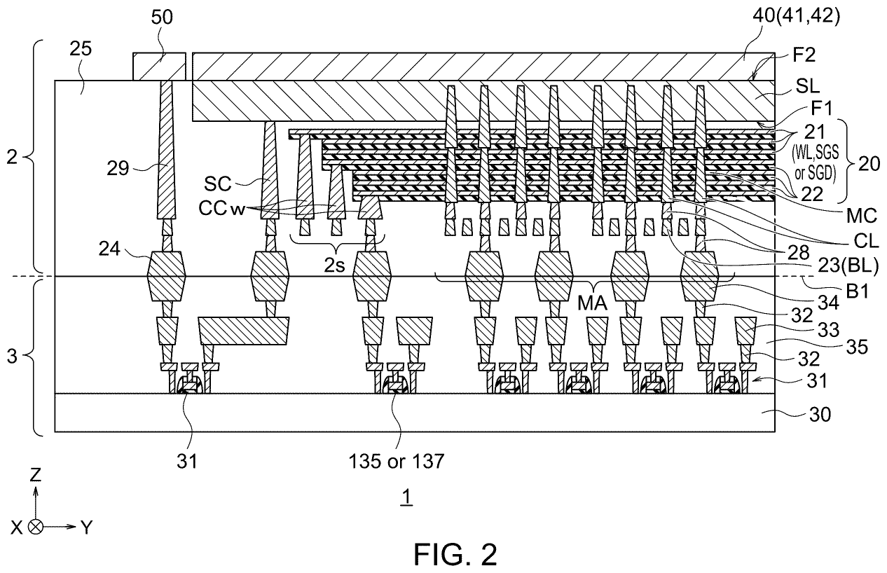

FIG. 2 is a sectional view illustrating a configuration example of a semiconductor storage device 1 according to a first embodiment. Hereinafter, the stacking direction of a stacked body 20 is assumed as a Z direction. One direction intersecting with, for example, being orthogonal to the Z direction is assumed as a Y direction. One direction intersecting with, for example, being orthogonal to the Z direction and the Y direction is assumed as an X direction.

The semiconductor storage device 1 includes an array chip 2 having a memory cell array MA, and a CMOS (Complementary Metal-Oxide Semiconductor) chip 3 having the peripheral circuits PC such as a CMOS circuit. The array chip 2 and the CMOS chip 3 are bonded on a bonding face B1 and are electrically connected to each other with lines joined on the bonding face. FIG. 2 illustrates a state in which the array chip 2 is located on the CMOS chip 3.

The CMOS chip 3 includes a substrate 30, transistors 31, 135, and 137, vias 32, lines 33 and 34, and an interlayer dielectric film 35.

The substrate 30 is, for example, a semiconductor substrate such as a silicon substrate. The transistors 31, 135, and 137 are NMOS or PMOS transistors provided on the substrate 30. The transistors 31 are low breakdown voltage (LV (Low voltage) or VLV (Very Low Voltage)) transistors and constitute, for example, a CMOS circuit that controls the memory cell array MA of the array chip 2. The transistors 31 constitute logic circuits such as a sense amplifier, a row decoder, and a column decoder. Therefore, the transistors 31 are required to operate at a high speed. Meanwhile, the transistors 135 and 137 are used as word line switches (drivers) for applying voltages to the word lines WL. Therefore, the transistors 135 are high breakdown voltage (HV) transistors having a higher breakdown voltage than the transistors 31 and function as block drive transistors of the block selection circuit 123 in FIG. 1. The transistors 137 are also high breakdown voltage transistors having a higher breakdown voltage than the transistors 31 and function as voltage selection transistors of the voltage selection circuit 124 in FIG. 1. It is preferable that the transistors 135 and 137 are high in the breakdown voltage, low in the threshold voltage, and low in the on-resistance while high-speed operations are also required. Semiconductor elements such as a resistive element and a capacitive element, other than the transistors 31, 135, and 137 may be formed on the substrate 30.

Each of the vias 32 electrically connects between one of the transistors 31, 135, and 137 and one of the lines 33 or between one of the lines 33 and one of the lines 34. The lines 33 and 34 constitute a multilayer wiring structure in the interlayer dielectric film 35. The lines 34 are embedded in the interlayer dielectric film 35 and are exposed on the surface of the interlayer dielectric film 35 to be substantially flush with the surface. The lines 33 and 34 are electrically connected to the transistors 31 and the like. For example, a metal such as copper or tungsten is used as the vias 32, and the lines 33 and 34. The interlayer dielectric film 35 coats and protects the transistors 31, 135, and 137, the vias 32, and the lines 33 and 34. For example, an insulating film such as a silicon dioxide film is used as the interlayer dielectric film 35.

The array chip 2 includes the stacked body 20, columnar bodies CL, slits ST (LI), a source layer SL, a metallic layer 40, contact plugs CCw, contact plugs 29, bonding pads 50, and an interlayer dielectric film 25.

The stacked body 20 is provided above the transistors 31, 135, and 137 and is positioned in the Z direction with respect to the substrate 30. The stacked body 20 is configured by alternately stacking a plurality of electrode films 21 and a plurality of insulating films 22 along the Z direction. The stacked body 20 constitutes the memory cell array MA. For example, a conductive metal such as tungsten is used as the electrode films 21. For example, an insulating film such as a silicon dioxide film is used as the insulating films 22. The insulating films 22 insulate the electrode films 21 from each other. That is, the electrode films 21 are stacked in a mutually insulated state. The numbers of stacked layers of the electrode films 21 and the insulating films 22 can be freely selected. The insulating films 22 may be, for example, porous insulating films or air gaps.

Ones or pluralities of the electrode films 21 at the top end and the bottom end of the stacked body 20 in the Z direction function as source-side selection gates SGS and drain-side selection gates SGD, respectively. Electrode films 21 between the source-side selection gates SGS and the drain-side selection gates SGD function as word lines WL. The word lines WL are gate electrodes of the memory cells MC. The source-side selection gates SGS are gate electrodes of source-side selection transistors. The drain-side selection gates SGD are gate electrodes of drain-side selection transistors. The source-side selection gates SGS are provided in an upper region of the stacked body 20. The drain-side selection gates SGD are provided in a lower region of the stacked body 20. The upper region indicates a region of the stacked body 20 on a side far from the CMOS chip 3 (a side close to the metallic layer 40), and the lower region indicates a region of the stacked body 20 on a side close to the CMOS chip 3.

The semiconductor storage device 1 includes a plurality of memory cells MC connected in series between one of the source-side selection transistors STS controlled by the source-side selection gates SGS and one of the drain-side selection transistors STD controlled by the drain-side selection gates SGD to constitute each memory string. Each of the memory strings is connected to, for example, a bit line BL through a via 28. The bit lines BL are lines 23 provided below the stacked body 20 and extending in the X direction (the depth direction of the drawing of FIG. 2). Therefore, the bit lines BL are hereinafter referred to also as “bit lines 23”.

A plurality of columnar bodies CL are provided in the stacked body 20. The columnar bodies CL extend in the stacked body 20 to penetrate through the stacked body 20 in the stacking direction (the Z direction) of the stacked body and are each located from a via 28 connected to a bit line 23 to the source layer SL. An internal structure of the columnar bodies CL will be described later. In the present embodiment, each of the columnar bodies CL is formed in two tiers in the Z direction. However, there is no problem with the columnar bodies CL in one tier. Alternatively, each of the columnar bodies CL may be formed in three or more tiers.

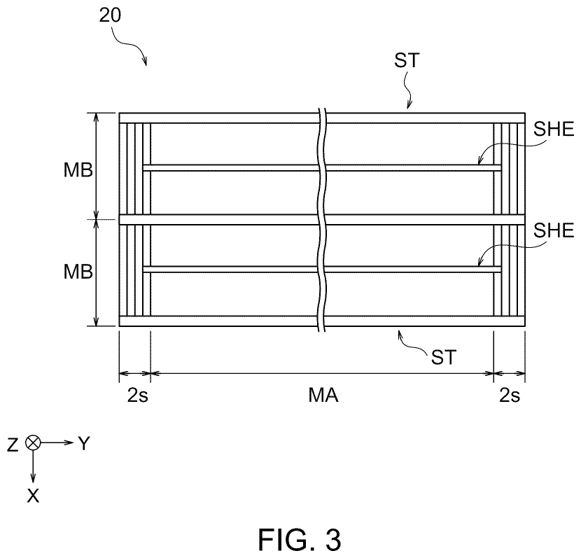

Although not illustrated in FIG. 2, a plurality of slits ST (see FIG. 3) are provided in the stacked body 20. The slits ST extend in the Y direction and penetrate through the stacked body 20 in the stacking direction (the Z direction) of the stacked body 20. An insulating film such as a silicon dioxide film is filled in each of the slits ST and the insulating film is configured in a plate shape. The slits ST electrically isolate the electrode films 21 of the stacked body 20. It is alternatively possible that the inner wall of each of the slits ST is coated with an insulating film such as a silicon dioxide film and that a conducting material is further embedded in the inner side of the insulating film. In this case, the conducting material can also function as a source line reaching the source layer SL.

The source layer SL is provided on the stacked body 20. The source layer SL is an example of a first semiconductor layer. The source layer SL is provided corresponding to the stacked body 20. The source layer SL has a face F1 and a face F2 on the opposite side to the face F1. The stacked body 20 (the memory cell array MA) is located on the side of the face F1 of the source layer SL, and the metallic layer 40 is located on the side of the face F2 thereof. The metallic layer 40 includes a source line 41 and a power-supply line 42. The source layer SL is connected in common to one ends of the columnar bodies CL and provides a plurality of columnar bodies CL in the same memory cell array MA with a common source potential. That is, the source layer SL functions as a common source electrode of the memory cell array MA. For example, a conductive material such as a doped polysilicon is used for the source layer SL. For example, a metallic material of a lower resistance than that of the source layer SL, such as copper, aluminum, or tungsten is used for the metallic layer 40. A reference sign 2s denotes a stepped portion of the electrode films 21 provided to connect each of the contact plugs CCw to an electrode film 21. The stepped portion 2s will be described later with reference to FIG. 3.

Meanwhile, the bonding pads 50 are provided in a region that is above the stacked body 20 and where the source layer SL is not located. The bonding pads 50 are connected to metallic wires or the like (not illustrated) and receive power supply or a signal from outside the semiconductor storage device 1. The bonding pads 50 are provided so as to be connected to one ends of the contact plugs 29 in the Z direction. The bonding pads 50 are connected to the transistors 31, 135, and 137 of the CMOS chip 3 via the contact plugs 29, the lines 24, and the lines 34. Accordingly, external power supplied from the bonding pads 50 are supplied to the transistors 31, 135, and 137. Alternatively, a signal or power is supplied to the transistors 31, 135, and 137 or the memory cell array MA via the bonding pads 50.

The contact plugs CCw are provided in a peripheral part of the stacked body 20 and extend in the Z direction in the interlayer dielectric film 25. Each of the contact plugs CCw is electrically connected between the electrode film 21 (a word line WL) and the line 24. The contact plugs CCw are provided at the stepped portions 2s each formed like stairs at each of the ends of the stacked body 20 and are each electrically connected to an associated electrode film 21. The contact plugs CCw are provided to transmit a word line voltage from the CMOS chip 3 to the associated electrode films 21. For example, a metal such as copper or tungsten is used for the contact plugs CCw.

The contact plugs 29 are provided in the peripheral part of the stacked body 20 and extend in the Z direction in the interlayer dielectric film 25. Each of the contact plugs 29 is a contact plug provided from the line 24 to the bonding pad 50. The contact plugs 29 are simultaneously formed in the same process as that of the contact plugs CCw connected to the word lines WL.

Each of the contact plugs 29 is electrically connected between the bonding pad 50 and the line 24. The contact plugs 29 are used to supply a power-supply voltage or a signal from the bonding pads 50 to the array chip 2 or the CMOS chip 3. For example, a metal such as copper or tungsten is used for the contact plugs 29. The power-supply voltage is, for example, a power-supply voltage VDD or a reference voltage (for example, a ground voltage) VSS lower than the power-supply voltage VDD. The signal may be a control signal from outside, or may be data to be written or read data.

In the present embodiment, the array chip 2 and the CMOS chip 3 are individually formed and are bonded on the boding face B1. Therefore, the transistors 31, 135, and 137 are not provided in the array chip 2. The stacked body 20 (the memory cell array MA) is not provided in the CMOS chip 3. The transistors 31, 135, and 137 and the stacked body 20 are both on the side of the face F1 of the source layer SL. The metallic layer 40 is located on the side of the face F2 of the source layer SL.

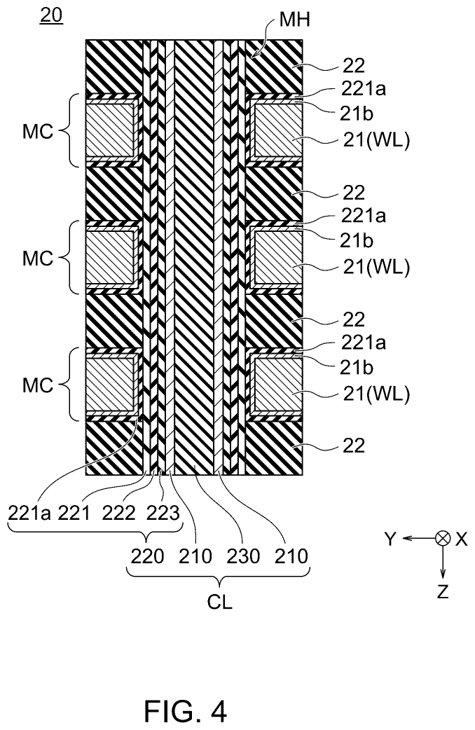

The vias 28, the lines 23, and the lines 24 are provided in the-Z direction of the stacked body 20. The lines 23 and 24 are embedded in the interlayer dielectric film 25. The lines 24 are exposed on the surface of the interlayer dielectric film 25 to be substantially flush with the surface. The lines 23 and 24 are electrically connected to semiconductor bodies 210 (see FIG. 4) of the columnar bodies CL. For example, a metal such as copper or tungsten is used for the vias 28, the lines 23, and the lines 24. The interlayer dielectric film 25 coats and protects the stacked body 20, the vias 28, the lines 23, and the lines 24. For example, an insulating film such as a silicon dioxide film is used as the interlayer dielectric film 25.

The interlayer dielectric film 25 and the interlayer dielectric film 35 are bonded on the bonding face B1 and, associated therewith, the lines 24 and the lines 34 are joined on the bonding face B1 to be substantially flush therewith. Accordingly, the array chip 2 and the CMOS chip 3 are electrically connected to each other via the lines 24 and the lines 34.

FIG. 3 is a schematic plan view illustrating the stacked body 20. The stacked body 20 includes the stepped portions 2s and the memory cell array MA. The stepped portions 2s are located, for example, at the ends of the stacked body 20. The memory cell array MA is sandwiched or surrounded by the stepped portions 2s. The slits ST (LI) are provided from the stepped portion 2s at one end of the stacked body 20 through the memory cell array MA to the stepped portion 2s at the other end of the stacked body 20. Slits SHE are provided at least on the memory cell array MA. The slits SHE are shallower in the Z direction than the slits ST (LI) and extend substantially in parallel to the slits ST (LI). The slits SHE electrically isolate the electrode films 21 for each of the drain-side selection gates SGD. The slits ST may be source lines LI electrically isolated from the electrode films 21 of the stacked body 20 while being electrically connected to the source layer SL. That is, the slits ST may be source lines LI electrically isolated from the electrode films 21 of the stacked body 20 constituting the memory cell array MA and electrically connected to the source layer SL.

A portion of the stacked body 20 sandwiched by two slits ST illustrated in FIG. 3 is a memory block MB. A memory block MB constitutes, for example, a minimum unit of data erasing. A slit SHE is provided in each memory block MB. The stacked body 20 between a slit ST and a slit SHE is referred to as “finger”. The drain-side selection gates SGD are divided for each finger. Accordingly, at the time of writing and reading data, one finger in a memory block MB can be brought to a selected state by the associated drain-side selection gate SGD.

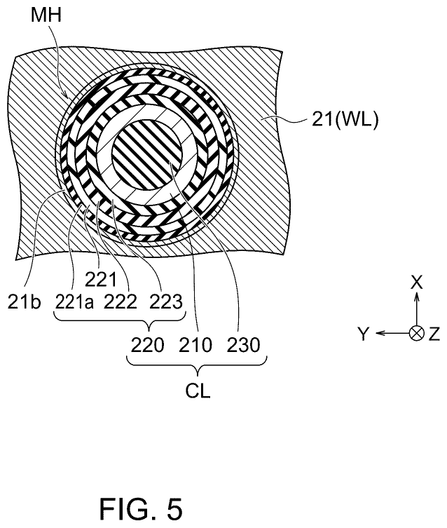

FIGS. 4 and 5 are sectional views illustrating memory cells of a three-dimensional structure. Each of the columnar bodies CL is provided in a memory hole MH formed in the stacked body 20. Each of the columnar bodies CL penetrates through the stacked body 20 along the Z direction from one end part of the stacked body 20 to be provided in the stacked body 20 and the source layer SL. Each of the columnar bodies CL includes the semiconductor body 210, a memory film 220, and a core layer 230. Each columnar body CL includes the core layer 230 located at a central part thereof, the semiconductor body (a semiconductor member) 210 located around the core layer 230, and the memory film 220 located around the semiconductor body 210. The semiconductor body 210 extends in the stacked body 20 in the stacking direction (the Z direction). The semiconductor body 210 is electrically connected to the source layer SL. The memory film 220 is located between the semiconductor body 210 and the electrode films 21 and has charge capturing parts. A plurality of the columnar bodies CL each selected from each of the fingers are connected in common to one bit line 23 through the vias 28 in FIG. 2. Each of the columnar bodies CL is provided, for example, in a region of the memory cell array MA.

As illustrated in FIG. 5, the shape of each of the memory holes MH in an X-Y plane is, for example, circular or elliptic. A block dielectric film 221a constituting a part of the memory film 220 may be provided between each of the electrode films 21 and adjacent insulating films 22. The block dielectric film 221a is, for example, a silicon oxide or a metal oxide. One example of the metal oxide is an aluminum oxide. A barrier film 21b may be provided between each of the electrode films 21 and adjacent insulating films 22 and between each of the electrode films 21 and the memory film 220. The barrier film 21b is, for example, a laminated film including titanium nitride and titanium, for example, in a case where the electrode films 21 are tungsten. The block dielectric film 221a suppresses back tunneling of charges from the electrode films 21 to the memory film 220. The barrier film 21b improves adhesion between the electrode films 21 and the block dielectric film 221a.

The shape of the semiconductor body 210 is, for example, a bottomed tube. For example, polysilicon is used as the semiconductor body 210. The semiconductor body 210 is, for example, undoped silicon. The semiconductor body 210 may be p-type silicon. The semiconductor body 210 functions as channels of the drain-side selection transistors, the memory cells MC, and the source-side selection transistors. That is, a plurality of the memory cells MC each have a storage region between the semiconductor body 210 and an electrode film 21 functioning as a word line WL and are stacked in the Z direction. One ends of a plurality of the semiconductor bodies 210 in the same memory cell array MA are electrically connected in common to the source layer SL.

The memory film 220 includes, for example, a cover dielectric film 221, a charge capturing film 222, a tunnel dielectric film 223, and the block dielectric film 221a. A portion of the memory film 220 other than the block dielectric film 221a is located between the inner wall of the memory hole MH and the semiconductor body 210. The shape of the memory film 220 is, for example, tubular. Each of the charge capturing film 223 extends in the Z direction. film 222 and the tunnel dielectric

The cover dielectric film 221 is located between the insulating films 22 and the charge capturing film 222 and between the block dielectric film 221a and the charge capturing film 222. The cover dielectric film 221 includes, for example, a silicon oxide. The cover dielectric film 221 protects the charge capturing film 222 from being etched when sacrificial films (not illustrated) are replaced by the electrode films 21 (in a replacement process). In a case where the replacement process is not used to form the electrode films 21, it is possible that the cover dielectric film 221 is not provided.

The charge capturing film 222 is located between the cover dielectric film 221 and the tunnel dielectric film 223. The charge capturing film 222 includes, for example, a silicon nitride and has a trap site that traps charges in the film. Portions of the charge capturing film 222 sandwiched between the electrode films 21 functioning as the word lines WL and the semiconductor body 210 constitute the storage regions of the memory cells MC as the charge capturing parts. A threshold voltage of each of the memory cells MC varies according to whether there are charges in the associated charge capturing part or the amount of charges captured in the charge capturing part. This causes each of the memory cells MC to retain information.

The tunnel dielectric film 223 is located between the semiconductor body 210 and the charge capturing film 222. The tunnel dielectric film 223 includes, for example, a silicon oxide, or a silicon oxide and a silicon nitride. The tunnel dielectric film 223 is a potential barrier between the semiconductor body 210 and the charge capturing film 222. For example, when electrons are injected from the semiconductor body 210 to the charge capturing film 222 (a write operation) and when positive holes are injected from the semiconductor body 210 to the charge capturing film 222 (an erase operation), the electrons and the positive holes each pass through (tunnel) the potential barrier of the tunnel dielectric film 223.

The core layer 230 fills the internal space of the tubular semiconductor body 210. The shape of the core layer 230 is, for example, columnar. The core layer 230 includes, for example, a silicon oxide and is insulative.

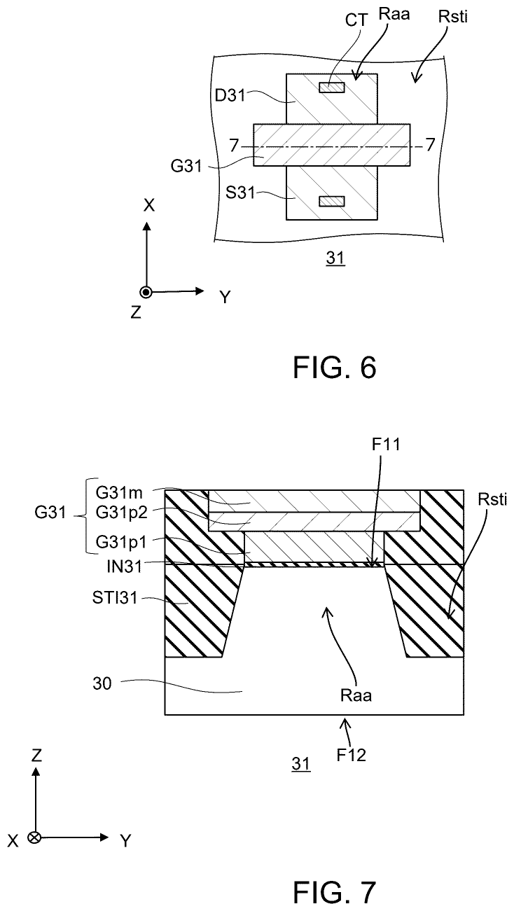

FIG. 6 is a plan view illustrating a configuration example of the transistors 31 constituting logic circuits of the CMOS chip 3 according to the first embodiment. FIG. 7 is a sectional view illustrating the configuration example of the transistors 31 constituting the logic circuits of the CMOS chip 3 according to the first embodiment. FIG. 7 illustrates a cross section along a line 7-7 in FIG. 6. FIGS. 6 and 7 illustrate a configuration of one transistor 31.

As illustrated in FIG. 6, convex regions Raa are surrounded by a concave region Rsti. The convex regions Raa are, for example, element formation regions (active areas). The concave region Rsti is, for example, a formation region of element isolation parts STI (Shallow Trench Isolation). The concave region Rsti is filled with an insulating material such as a silicon dioxide film around the convex regions Raa on which the transistors 31 are formed.

Each of the transistors 31 has a drain D31 located on the convex region Raa on one side of a gate electrode G31, and has a source S31 located on the convex region Raa on the other side of the gate electrode G31.

Contacts CT are electrically connected to the lines 33 and 34 through the vias 32 or the like.

The substrate 30 in FIG. 7 can be, for example, a semiconductor substrate such as a silicon substrate. The substrate 30 is one example of a semiconductor layer. The substrate 30 includes a first face F11 on which control circuits including the transistors 31, 135, and 137, and the like are provided, and a second face F12 on the opposite side to the first face F11. The substrate 30 has the concave region Rsti on the side of the first face F1, which is recessed from the first face F11 toward the second face F12. The concave region Rsti is, for example, filled with an insulating film such as a silicon dioxide film and constitutes shallow trench isolation parts STI31. The shallow trench isolation parts STI31 electrically isolate adjacent transistors 31 from each other. The substrate 30 has the convex regions Raa protruded with respect to the concave region Rsti. The convex regions Raa are surrounded by the concave region Rsti and are defined by the concave region Rsti.

The transistors 31 are provided on the first faces F11 of the convex regions Raa. Each of the transistors 31 includes a gate dielectric film IN31 and a gate electrode G31.

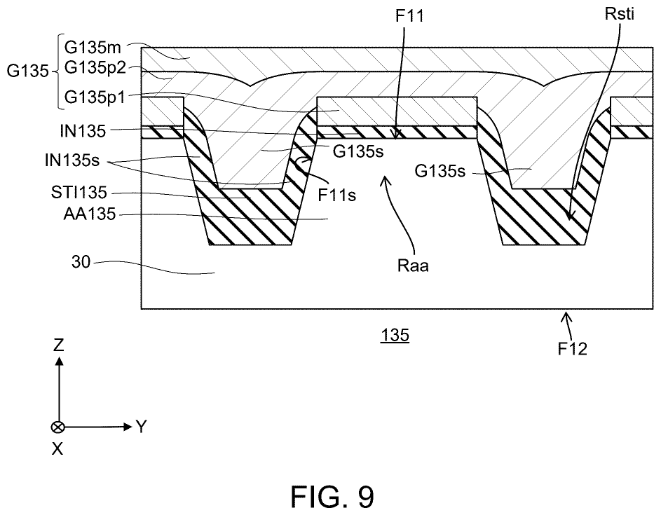

The gate dielectric film IN31 is provided on the first faces F11 of the convex regions Raa. The film thickness of the gate dielectric film IN31 is smaller than that of a gate dielectric film IN135 of the transistors 135 illustrated in FIG. 9. For example, an insulating film such as a silicon dioxide film is used as the gate dielectric film IN31. The gate electrode G31 is provided on the gate dielectric film IN31.

The gate electrode G31 is constituted of, for example, a laminated film including a first gate electrode part G31p1, a second gate electrode part G31p2, and a third gate electrode part G31m. The first and second gate electrode parts G31p1 and G31p2 are, for example, a conducting material such as doped polysilicon including boron as impurities. For example, a conductive metallic material such as tungsten or copper is used for the third gate electrode part G31m.

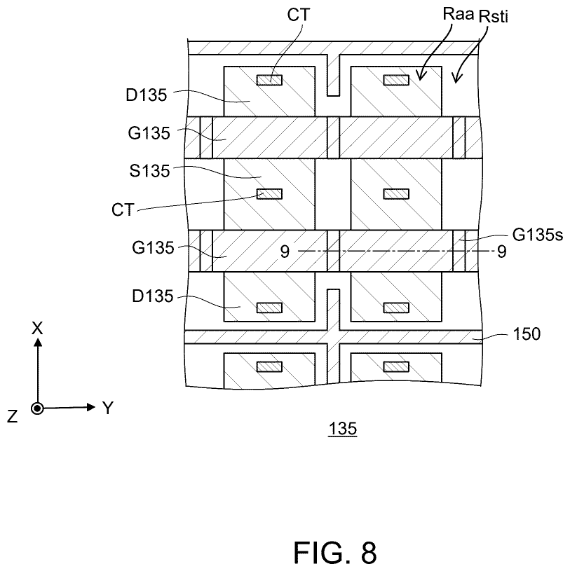

FIG. 8 is a plan view illustrating a configuration example of the transistors 135 constituting word line switches of the CMOS chip 3 according to the first embodiment. FIG. 9 is a sectional view illustrating the configuration example of the transistors 135 constituting the word line switches of the CMOS chip 3 according to the first embodiment. FIG. 9 illustrates a cross section along a line 9-9 in FIG. 8. FIGS. 8 and 9 illustrate the configuration of four transistors 135. The configuration of the transistors 137 can be the same as that of the transistors 135. Therefore, explanations of the configuration of the transistors 137 are omitted here.

As illustrated in FIG. 8, the convex regions Raa are surrounded by the concave region Rsti. Each of the transistors 135 has a drain D135 provided in the convex region Raa on one side of a gate electrode G135, and has a source S135 provided in the convex region Raa on the other side of the gate electrode G135. In FIG. 8, a plurality of the transistors 135 share the source S135.

A reference voltage source 150 is formed in the concave region Rsti and is constituted of the same material as that of the gate electrodes G135. The reference voltage source 150 is electrically connected to the substrate 30, is kept at a predetermined reference voltage (for example, a ground voltage), and electrically isolates transistors from each other.

The substrate 30 in FIG. 9 is the same substrate as the substrate 30 in FIG. 7. Therefore, the transistors 31, 135, and 137 are formed on the same substrate 30.

The transistors 135 are located on the first faces F11 of the convex regions Raa. Each of the transistors 135 includes a gate dielectric film IN135, a side gate dielectric film IN135s, the gate electrode G135, and side gate electrodes G135s.

The gate dielectric film IN135 is located on the first faces F11 of the convex regions Raa. The film thickness of the gate dielectric film IN135 is larger than that of the gate dielectric film IN31 of the transistors 31 described above. The film thickness of the gate dielectric film IN31 is, for example, equal to or less than 10 nanometers (nm) and the film thickness of the gate dielectric film IN135 is, for example, equal to or more than 30 nm. For example, an insulating film such as a silicon dioxide film is used as the gate dielectric film IN135.

The side gate dielectric film IN135s is located on side surfaces F11s of the convex regions Raa. That is, the side gate dielectric film IN135s is located in concave portions of the concave region Rsti and is located on shallow trench isolation parts STI135. The thickness of the side gate dielectric film IN135s is larger than that of the gate dielectric film IN135. Accordingly, the breakdown voltage can be kept high while the gate width of the transistors 135 is increased. For example, an insulating film such as a silicon dioxide film is used as the side gate dielectric film IN135s similarly to the gate dielectric film IN135.

The gate electrode G135 is located on the gate dielectric film IN135. The gate electrode G135 is constituted of, for example, a laminated film including a first gate electrode part G135p1, a second gate electrode part G135p2, and a third gate electrode part G135m. The first and second gate electrode parts G135p1 and G135p2 are in the same layers as the first and second gate electrode parts G31p1 and G31p2, respectively, and include, for example, boron as impurities. The third gate electrode part G135m is in the same layer as the third gate electrode part G31m and, for example, a conductive metallic material such as tungsten or copper is used therefor. The third gate electrode part G135m does not need to be a metallic material and it suffices that the third gate electrode part G135m is a material lower in the resistance than the first and second gate electrode parts G31p1 and G31p2.

While each having a laminated structure including three layers in the present embodiment, the gate electrodes G31 and G135 may each be a single conducting layer, or have a laminated structure including two layers, or four or more layers.

The side gate electrodes G135s are located on the side gate dielectric film IN135s and are connected to the gate electrode G135 on the first face F11. The side gate electrodes G135s are configured in the same layer as that of the first gate electrode part G135p1.

The side gate electrodes G135s are located in the concave portions of the concave region Rsti and are each embedded between the side gate dielectric films IN135s on the shallow trench isolation parts STI135.

Each of the side gate electrodes G135s is constituted of the second gate electrode part G135p2 in the laminated structures of the gate electrodes G31 and G135 in the present embodiment. However, each of the side gate electrodes G135s may be constituted of the third gate electrode part G135m. Each of the side gate electrodes G135s may have a laminated structure including two or more layers.

The contacts CT are electrically connected to the lines 33 or 34 through the vias 32 or the like. The contacts CT on the source side or the drain side are electrically connected to the word lines WL through the contact plugs CCw of the array chip 2.

In the formation region of the transistors 135, only bottom portions of the concave regions Rsti are filled with, for example, an insulating film such as a silicon dioxide film and constitute the shallow trench isolation parts STI135. Each of the shallow trench isolation parts STI135 electrically isolates adjacent transistors 135 from each other. The transistors 31, 135, and 137 in FIGS. 7 to 9 may be provided on the same substrate 30 and on the same convex regions Raa.

According to the present embodiment, the transistors 31 constituting the logic circuits of the peripheral circuits PC of the CMOS chip 3 are low breakdown voltage (LV or VLV) transistors that each have the first face F11 of the active area Raa as a channel region and does not have a channel region on the side surfaces of the active area Raa as illustrated in FIG. 7. Accordingly, the logic circuits of the peripheral circuits PC consume low power, can perform a high-speed operation, and are efficiently downscaled.

Meanwhile, the block drive transistors 135 of the block selection circuit 123 and the voltage selection transistors 137 of the voltage selection circuit 124 are high breakdown voltage (HV) transistors that each have both the first face F11 and the side surfaces F11s of the active area Raa as a channel region and have the gate dielectric film IN135 thicker than that of the transistors 31 as illustrated in FIG. 9. Therefore, the channel widths (the gate widths) of the transistors 135 and 137 functioning as the word line switches (drivers) of the peripheral circuits PC are widened, which decreases the on-resistance and can improve the current drive capability for the word lines WL. Since the side surfaces F11s of the active area Raa are used as the channel region, increase in the planar sizes (the dimensions in the gate width direction) of the transistors 135 and 137 can be suppressed. Further, in a case where the current drive capability is maintained constant, the planar sizes (the dimensions in the gate width direction) of the transistors 135 and 137 can be decreased. In a case where a plurality of the transistors 135 and 137 are arranged in parallel as the word line switches, the interval (pitch) between the transistors 135 or the interval (pitch) between the transistors 137 can be decreased while the current drive capabilities of the transistors 135 and 137 are maintained.

The thickness of the side gate dielectric film IN135s of the transistors 135 and 137 is larger than that of the gate dielectric film IN135. Accordingly, the breakdown voltages of the transistors 135 and 137 can be kept to be substantially the same as that of the high breakdown voltage transistors that do not have a channel region on the side surfaces F11s. As a result, the transistors 135 and 137 according to the present embodiment can provide both the low on-resistance and the high breakdown voltage while maintaining the threshold voltage.

### Manufacturing Method of Transistors 31, 135, and 137

A manufacturing method of the transistors 31, 135, and 137 is explained next.

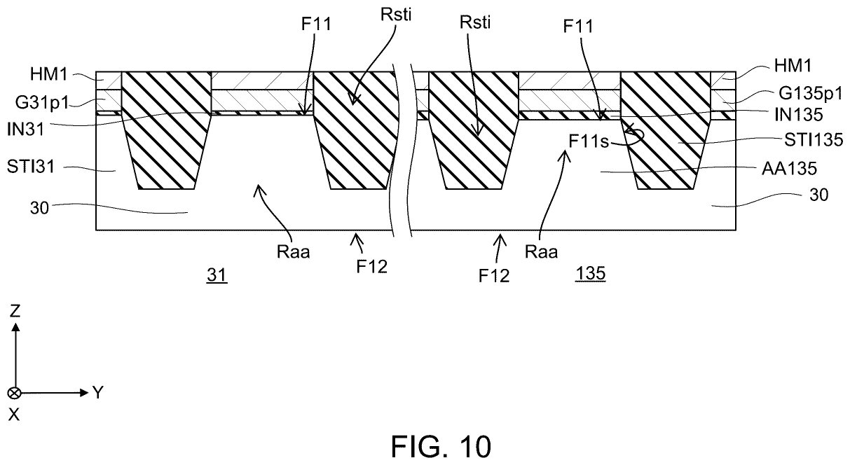

FIGS. 10 to 15 are sectional views illustrating an example of the manufacturing method of the transistors 31, 135, and 137 according to the first embodiment. The transistors 31, 135, and 137 are formed on the same substrate 30. FIGS. 10 to 15 illustrate a transistor 31 and a transistor 135 side by side and illustrations of the transistors 137 are omitted. The transistors 137 can be formed in the same manner as the transistors 135.

The gate dielectric films IN31 and IN135 are formed on the first face F11 of the substrate 30. The gate dielectric film IN135 is formed thicker than the gate dielectric film IN31. For example, after an insulating film such as a silicon dioxide film is formed on the entire first face F11, the insulating film in the formation region of the gate dielectric film IN31 is selectively removed using a lithography technique and an etching technique, and the insulating film such as a silicon dioxide film is subsequently formed again on the entire first face F11. In this way, a relatively thick insulating film can be formed in the formation region of the gate dielectric film IN135, and a relatively thin insulating film can be formed in the formation region of the gate dielectric film IN31.

Next, a material (for example, doped polysilicon) of the first gate electrode parts G31p1 and G135p1 is formed on the gate dielectric films IN31 and IN135, and a material (for example, a silicon nitride film) of a hard mask HM1 is formed on the material of the first gate electrode parts G31p1 and G135p1.

Next, the material of the hard mask HM1 in the concave region Rsti is selectively etched using a lithography technique and an etching technique. The material of the first gate electrode parts G31p1 and G135p1, the gate dielectric films IN31 and IN135, and the substrate 30 are processed using the hard mask HM1 as a mask. Accordingly, trenches are formed in the concave region Rsti.

Next, a material (for example, a silicon dioxide film) of the shallow trench isolation parts STI31 and STI135 is formed in the trenches of the concave region Rsti. The material of the shallow trench isolation parts STI31 and STI135 is flattened using a CMP (Chemical Mechanical Polishing) method or the like. A structure illustrated in FIG. 10 is thereby obtained.

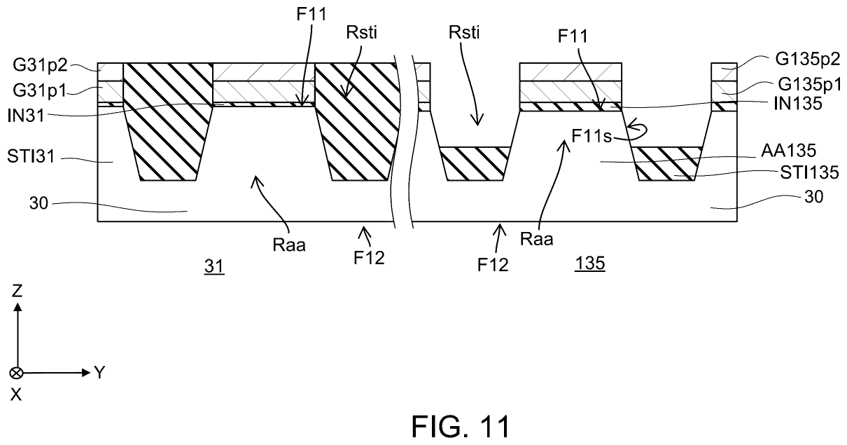

Next, the material of the shallow trench isolation parts STI135 is selectively etched using a lithography technique and an etching technique. As illustrated in FIG. 11, in the formation region of the transistors 135, an upper portion of the material of the shallow trench isolation parts STI135 in the concave region Rsti is removed to cause the shallow trench isolation parts STI135 to remain at the bottom portions of the concave region Rsti. Accordingly, the side surfaces F11s of the active area Raa (portions of the sidewall of the concave region Rsti) are exposed in the formation region of the transistors 135. The shallow trench isolation parts STI135 in the formation region of the transistors 135 function as element isolation regions of the transistors 135. Meanwhile, in the formation region of the transistors 31, the concave region Rsti is kept filled with the material of the shallow trench isolation parts STI31 as illustrated in FIG. 11. The shallow trench isolation parts STI31 in the formation region of the transistors 31 function as element isolation regions of the transistors 31.

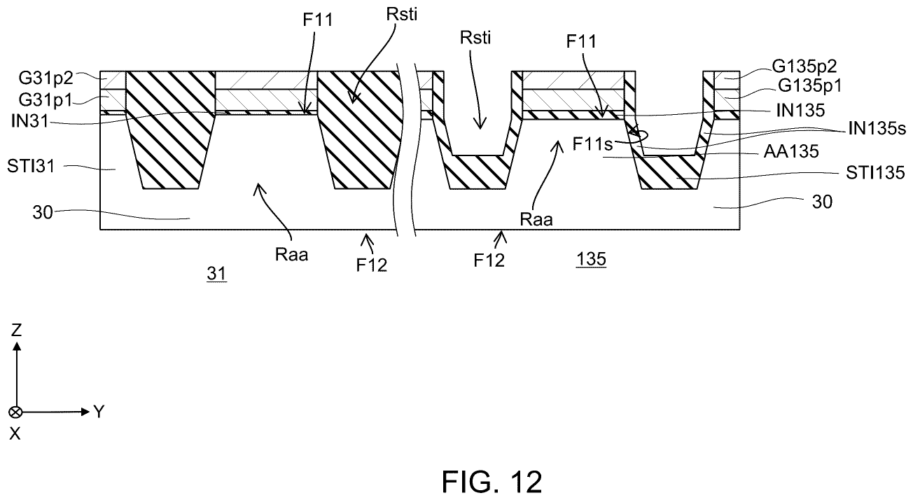

Next, a material (for example, a silicon dioxide film) of the side gate dielectric film IN135s is formed on the side surfaces F11s of the active areas Raa and the hard mask MH1. Next, the material of the side gate dielectric film IN135s is etched back. Accordingly, the side gate dielectric film IN135s is left on the side surfaces F11s of the active areas Raa in the formation region of the transistors 135 as illustrated in FIG. 12. The structure in the formation region of the transistors 31 in FIG. 12 is unchanged from that in FIG. 11.

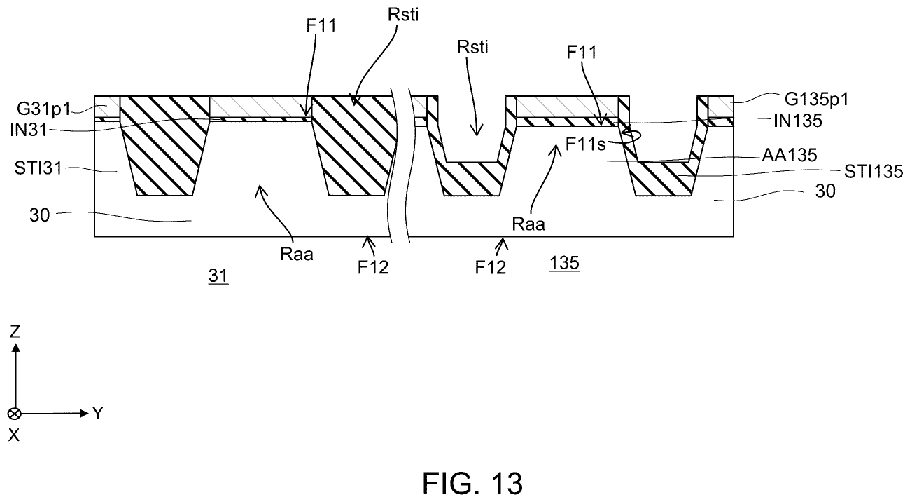

Next, the hard mask HM1 is removed using a hot phosphoric acid solution or the like as illustrated in FIG. 13.

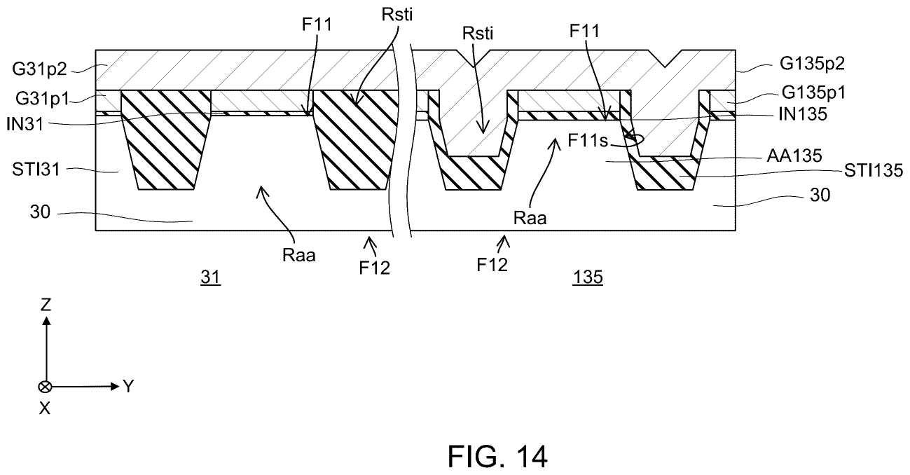

Next, a material (for example, doped polysilicon) of the gate electrode parts G31p2 and G135p2 is deposited on the shallow trench isolation parts STI31 and STI135, the side gate dielectric film IN135s, and the gate electrode parts G31p1 and G135p1 as illustrated in FIG. 14. Accordingly, the gate electrode part G135p2 is embedded in the inner side of the concave region Rsti in the formation region of the transistors 135. The gate electrode part G135p2 opposes the side surfaces F11s of the active areas Raa with the side gate dielectric film IN135s interposed therebetween, and contributes to increase in the channel width (the gate width) of the transistors 135.

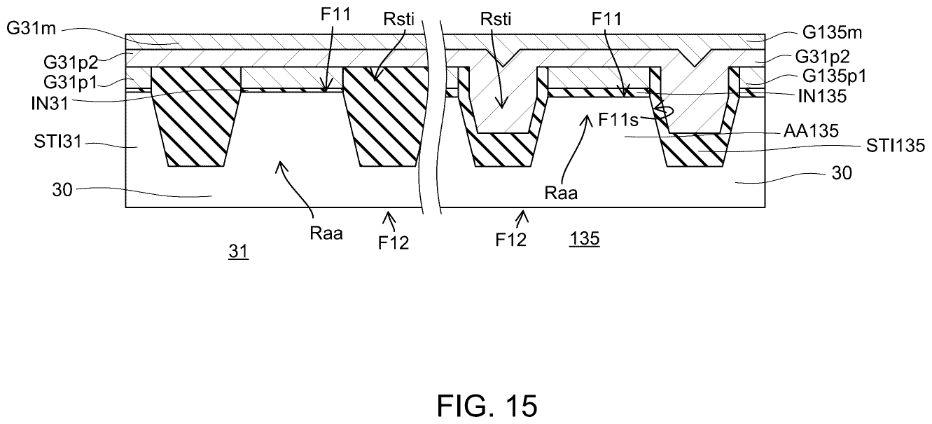

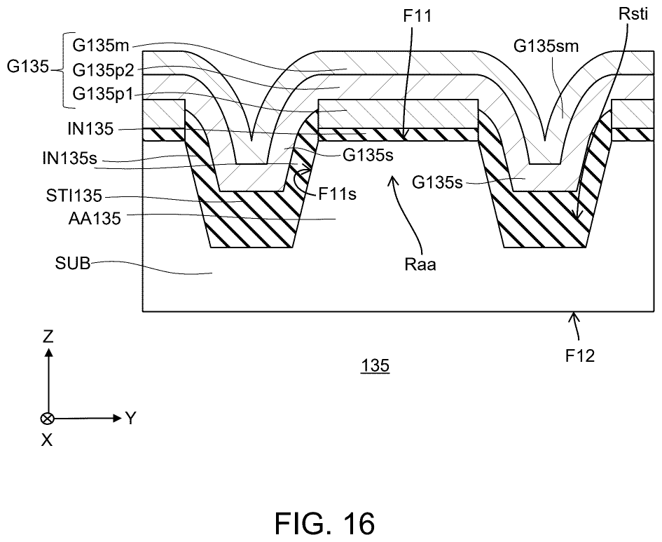

Next, an upper portion of the material of the gate electrode parts G31p2 and G135p2 is etched back. Next, as illustrated in FIG. 15, a material (for example, tungsten) of the third gate electrode parts G31m and G135m is deposited on the gate electrode parts G31p2 and G135p2. The gate electrodes G31 and G135 are thereby formed.

Next, an interlayer dielectric film, via contacts, a wiring structure, and the like are formed on the gate electrodes G31 and G135 to complete the CMOS chip 3 although not illustrated.

Subsequently, the CMOS chip 3 and the array chip 2 formed separately from the CMOS chip 3 are bonded to each other, whereby the semiconductor storage device 1 illustrated in FIG. 2 is completed.

As described above, according to the present embodiment, the transistors 135 and 137 can be simultaneously formed on the same substrate as that for the transistors 31 in common semiconductor manufacturing processes. Accordingly, fewer additional manufacturing processes are required and increase in the manufacturing cost is suppressed.

### Second Embodiment

FIG. 16 is a sectional view illustrating a configuration example of the transistors 135 constituting word line switches according to a second embodiment. The configuration of the transistor 137 may be the same as that of the transistor 135. Therefore, explanations of the configuration of the transistor 137 will be omitted.

In the second embodiment, the material (for example, doped polysilicon) of the side gate electrodes G135s in the concave region Rsti of the transistors 135 does not fill the concave region Rsti while coating the side gate dielectric film IN135s.

Meanwhile, the material (for example, tungsten) of the third gate electrode part G135m coats over the side gate electrodes G135s in the concave region Rsti. The material of the third gate electrode part G135m may be filled in the concave region Rsti. Even with this configuration, the transistor 135 according to the second embodiment has functions identical to those of the transistor 135 according to the first embodiment.

Other configurations of the second embodiment may be identical to those of the first embodiment. Therefore, the second embodiment can attain effects identical to those of the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first semiconductor layer comprising a first face and a second face on an opposite side to the first face, and comprising a concave region recessed from the first face toward the second face and a convex region protruded with respect to the concave region;
first transistors each comprising a first gate dielectric film located in the convex region of the first semiconductor layer, a side gate dielectric film located on sidewalls of the convex region, a first gate electrode located on the first gate dielectric film, and a side gate electrode located on the side gate dielectric film and connected to the first gate electrode; and
second transistors each comprising a second gate dielectric film located on the convex region and being thinner than the first gate dielectric film, and a second gate electrode located on the second gate dielectric film.

2. The device of claim 1, wherein the side gate dielectric film is thicker than the first gate dielectric film.

3. The device of claim 1, wherein
each of the first and second gate electrodes is constituted of a laminated film including a first conducting layer and a second conducting layer located on the first face of the convex region, and
the side gate electrode is constituted of the second conducting layer located on the side gate dielectric film.

4. The device of claim 1, wherein the first and second transistors are located in the same convex region.

5. The device of claim 1, further comprising
a memory cell array comprising a plurality of memory cells each provided corresponding to one of intersections between first lines and second lines and each enabling data to be written therein or read therefrom through an associated one of the second lines by application of a voltage to an associated one of the first lines, wherein
sources or drains of the first transistors are electrically connected to the first lines.

6. The device of claim 5, wherein a first chip comprising the first transistors, the second transistors, and the first semiconductor layer and a second chip comprising the memory cell array are bonded to each other.

7. The device of claim 1, wherein an insulating material as well as the side gate dielectric film and the side gate electrode is filled in the concave region.

8. A semiconductor device comprising:
a first semiconductor layer comprising a first face and a second face on an opposite side to the first face, and comprising a concave region recessed from the first face toward the second face and a convex region protruded with respect to the concave portion; and
first transistors each comprising a first gate dielectric film located in the convex region of the first semiconductor layer, a side gate dielectric film located on sidewalls of the convex region and being thicker than the first gate dielectric film, a first gate electrode located on the first gate dielectric film, and a side gate electrode located on the side gate dielectric film and connected to the first gate electrode.

9. The device of claim 8, wherein
the first gate electrode is constituted of a laminated film including a first conducting layer and a second conducting layer located on the first face of the convex region, and
the side gate electrode is constituted of the second conducting layer located on the side gate dielectric film.

10. The device of claim 8, further comprising
second transistors each comprising a second gate dielectric film located on the convex region and being thinner than the first gate dielectric film, and a second gate electrode located on the second gate dielectric film, wherein
the first and second transistors are located in the same convex region.

11. The device of claim 10, further comprising
a memory cell array comprising a plurality of memory cells each provided corresponding to one of intersections between first lines and second lines and each enabling data to be written therein or read therefrom through an associated one of the second lines by application of a voltage to an associated one of the first lines, wherein
sources or drains of the first transistors are electrically connected to the first lines.

12. The device of claim 11, wherein a first chip comprising the first transistors, the second transistors, and the first semiconductor layer and a second chip comprising the memory cell array are bonded to each other.

13. The device of claim 8, wherein an insulating material as well as the side gate dielectric film and the side gate electrode is filled in the concave region.

14. A semiconductor device comprising:
a memory cell array comprising a plurality of memory cells each provided corresponding to one of intersections between first lines and second lines and each enabling data to be written therein or read therefrom through an associated one of the second lines by application of a voltage to an associated one of the first lines;
a first semiconductor layer comprising a first face and a second face on an opposite side to the first face, and comprising a concave region recessed from the first face toward the second face and a convex region protruded with respect to the concave region; and
first transistors each comprising a first gate dielectric film located in the convex region of the first semiconductor layer, a side gate dielectric film located on sidewalls of the convex region, a first gate electrode located on the first gate dielectric film, and a side gate electrode located on the side gate dielectric film and connected to the first gate electrode, wherein
sources or drains of the first transistors are electrically connected to the first lines.

15. The device of claim 14, wherein the side gate dielectric film is thicker than the first gate dielectric film.

16. The device of claim 15, wherein
each of the first and second gate electrodes is constituted of a laminated film including a first conducting layer and a second conducting layer located on the first face of the convex region, and
the side gate electrode is constituted of the second conducting layer located on the side gate dielectric film.

17. The device of claim 14, further comprising
second transistors each comprising a second gate dielectric film located on the convex region and being thinner than the first gate dielectric film, and a second gate electrode located on the second gate dielectric film, wherein
the first and second transistors are located in the same convex region.

18. The device of claim 17, wherein a first chip comprising the first transistors, the second transistors, and the first semiconductor layer and a second chip comprising the memory cell array are bonded to each other.

19. The device of claim 14, wherein an insulating material as well as the side gate dielectric film and the side gate electrode is filled in the concave region.
